(19) United States
(12) Patent Application Publication
(10) Pub. No.: US 2021/0351280 A1
(43) Pub. Date: Nov. 11, 2021

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventor: Li Zhang, Hefei (CN)

(21) Appl. No.: 17/385,011

(22) Filed: Jul. 26, 2021

Related U.S. Application Data
(63) Continuation of application No. PCT/CN2021/080361, filed on Mar. 12, 2021.

(30) Foreign Application Priority Data
Mar. 30, 2020 (CN) 202010238785.1

(51) Int. Cl. H01L 29/66

(52) U.S. Cl. CPC H01L 29/6656; H01L 21/28202

(57) ABSTRACT

A method for manufacturing a semiconductor structure includes: providing a substrate; forming at least a pair of first side walls on the substrate, an interval being provided distance between two first side walls in each pair; forming a second side wall at either side of each of the first side walls by an In-Situ Steam Generation (ISSG) process, and forming a gate oxide layer on the substrate between the two first side walls in each pair; and forming a gate layer on a surface of the gate oxide layer.

### CROSS-REFERENCE TO RELATED APPLICATION

The present application is a U.S. continuation application of International Application No. PCT/CN2021/080361, filed on Mar. 12, 2021, which claims priority to Chinese Patent Application No. 202010238785.1, filed on Mar. 30, 2020. International Application No. PCT/CN2021/080361 and Chinese Patent Application No. 202010238785.1 are incorporated herein by reference in their entireties.

### TECHNICAL FIELD

The disclosure relates to the field of semiconductors, and particularly relates to a semiconductor structure and a method for manufacturing the same.

### BACKGROUND

As the size of complementary metal oxide semiconductor (CMOS) device is gradually reduced to the sub-micron level, the number of transistors in high-efficiency and high-density integrated circuits has increased to tens of millions, as predicted by the Moore's law, resulting in continuous reduction of the thickness of side wall of a gate electrode and the thickness of a gate oxide layer. In existing processes, the oxide layer on the side wall of the gate electrode is generally formed by an Atomic Layer Deposition (ALD) process. The oxide layer formed by the ALD process on the side wall has many defects and lower breakdown voltage, which will increase the leakage current of the gate electrode, generating a great impact on the reliability and service life of the device.

### SUMMARY

According to the examples, the disclosure provides a semiconductor structure and a method for manufacturing the same. The semiconductor structure has the effect of reducing the leakage current of a gate electrode.

The method for manufacturing the semiconductor structure includes the following operations.

A substrate is provided.

At least a pair of first side walls are formed on the substrate and an interval is provided between two first side walls in each pair.

A second side wall is formed at either side of each of the first side walls by an In-Situ Steam Generation (ISSG) process, and a gate oxide layer is formed on the substrate between two first side walls in each pair.

And, a gate layer is formed on a surface of the gate oxide layer.

Through the above technical solution, since the second side wall is formed by ISSG, the second side wall would have a higher breakdown voltage, and would have fewer defects inside. Moreover, the second side wall formed at either side of each of the first side walls can on the one hand, improve the ability of the first side wall and the second side wall to reduce the leakage current of the gate electrode. On the other hand, the second side wall formed at either side of each of the first side walls can reduce the thickness of the second side wall at either side of the first side wall, so as to reduce the possibility of defects in the second side wall. Therefore, the ability of the first side walls and the second side walls to reduce the leakage current of the gate electrode can be further improved, and the reliability and the service life of the device can be increased.

In one example, the formation of the first side walls on the substrate includes the following operations.

A sacrificial layer is formed on the substrate.

Side wall grooves are formed in the sacrificial layer.

The first side walls are formed in the side wall grooves.

And, the sacrificial layer is removed.

In one example, each of the first side walls includes a silicon-containing dielectric layer.

In one example, each of the first side walls includes a silicon nitride layer or silicon dioxide layer, and the second side wall includes a silicon dioxide layer.

In one example, a shallow groove isolation structure is formed in the substrate. The shallow groove isolation structure isolates a plurality of active regions in the substrate. The first side walls, the second side walls, and the gate oxide layer are located on the active regions.

In one example, after the gate layer is formed, the method further includes an operation of forming a top dielectric layer on a surface of the gate layer.

In one example, the top dielectric layer includes a silicon nitride layer or a silicon oxide layer.

In one example, the formation of the second side wall by the In-Situ Steam Generation process is performed under a reaction temperature of 800° C. to 1100° C., and a reaction pressure of 6 Torr to 20 Torr.

In one example, the formation of the second side wall by the In-Situ Steam Generation process is performed by a reaction gas comprising a mixed gas of oxygen and hydrogen, a mixed gas of nitric oxide and hydrogen or a mixed gas of nitrogen dioxide and hydrogen.

In one example, a volume concentration of hydrogen in the mixed gas is 1% to 33%.

In one example, the semiconductor structure is manufactured according to the above method for manufacturing the semiconductor structure.

### BRIEF DESCRIPTION OF THE DRAWINGS

FIG. 1 illustrates a flowchart of a method for manufacturing a semiconductor structure shown in one example.

FIG. 2 illustrates a flowchart of a method for manufacturing a semiconductor structure shown in another example.

FIG. 3 schematically illustrates a cross-sectional structure in one example in which a sacrificial layer has been formed on a substrate.

FIG. 4 schematically illustrates a cross-sectional structure in one example in which a photoresist layer has been formed.

FIG. 5 schematically illustrates a cross-sectional structure in one example in which side wall grooves have been formed.

FIG. 6 schematically illustrates a cross-sectional structure in one example in which first side walls have been formed.

FIG. 7 schematically illustrates a cross-sectional structure in one example in which the sacrificial layer has been removed.

FIG. 8 schematically illustrates a cross-sectional structure in another example in which a sacrificial layer has been formed on a substrate.

FIG. 9 schematically illustrates a cross-sectional structure in another example in which a first side wall material layer has been formed.

FIG. 10 schematically illustrates a cross-sectional structure in another example in which the first side wall material layer has been removed from an upper surface of the substrate and an upper surface of the sacrificial layer.

FIG. 11 schematically illustrates a cross-sectional structure in another example in which a sacrificial layer has been removed.

FIG. 12 schematically illustrates a cross-sectional structure in an example in which a second side wall and a gate oxide layer have been formed.

FIG. 13 schematically illustrates a cross-sectional structure in another example in which a second side wall has been formed.

FIG. 14 schematically illustrates a cross-sectional structure in another example in which a gate oxide layer has been formed.

FIG. 15 schematically illustrates a cross-sectional structure in one example in which a gate layer has been formed.

FIG. 16 schematically illustrates a cross-sectional structure in one example in which a top dielectric layer has been formed.

### DETAILED DESCRIPTION

In order to facilitate the understanding of the disclosure, the disclosure will be described more fully below with reference to accompanying drawings. The drawings show preferred examples of the disclosure. However, the disclosure can be implemented in many different forms and is not limited to the examples described herein. On the contrary, the purpose of providing these examples is to make the content of the disclosure more thorough and comprehensive.

Unless otherwise defined, all technical and scientific terms used herein have the same meanings as commonly understood by those skilled in the art to which the disclosure belongs. The terms used in the specification of the disclosure herein are merely for the purpose of describing specific examples, but are not intended to limit the disclosure. The term “and/or” as used herein includes any and all combinations of one or more of the related listed items.

In the description of the disclosure, it should be understood that the orientations or position relationships indicated by terms “upper”, “lower”, “vertical”, “horizontal”, “inner”, “outer” and the like are based on the orientations or position relationships shown in accompanying drawings. These terms are only for the convenience of describing the disclosure and simplifying the description, rather than indicating or implying that the device or element referred to must have a specific orientation, be constructed and operated along the specific orientation, so cannot be understood as a limitation to the disclosure.

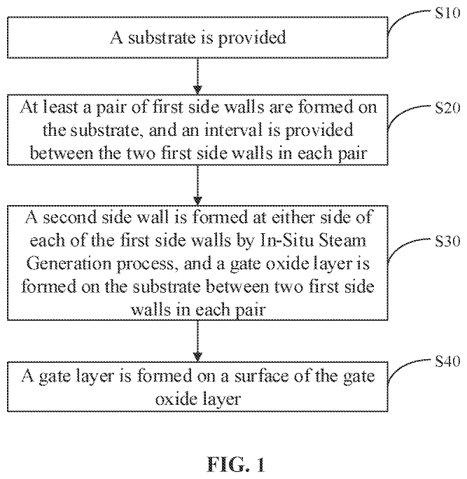

As shown in FIG. 1, a method for manufacturing a semiconductor structure according to one example is provided. The method specifically includes the following operations.

At S10, a substrate 10 is provided.

At S20, at least a pair of first side walls 11 are formed on the substrate 10, and an interval is provided between two first side walls in each pair.

At S30, a second side wall 12 is formed at either side of each of the first side walls 11 by an ISSG process, and a gate oxide layer 13 is formed on the substrate 10 between two first side walls 11 in each pair.

At S40, a gate layer 14 is formed on a surface of the gate oxide layer 13.

In an optional example, for S10, as shown in FIG. 3, specifically, the substrate 10 may be a silicon substrate, a silicon-on-insulator substrate, or includes other semiconductor materials such elements of group III, group IV and group V. A shallow trench isolation structure 19 is formed in the substrate 10, and isolates a plurality of active regions in the substrate 10. Each of the active regions may be doped with doped ions, such as N-type ions or P-type ions. The plurality of active regions are arranged at intervals in the substrate 10.

In an optional example, S20 specifically includes the following operations.

At S201, a sacrificial layer 15 is formed on the substrate 10, as shown in FIG. 3.

At S202, side wall grooves 16 are formed in the sacrificial layer 15, as shown in FIG. 5.

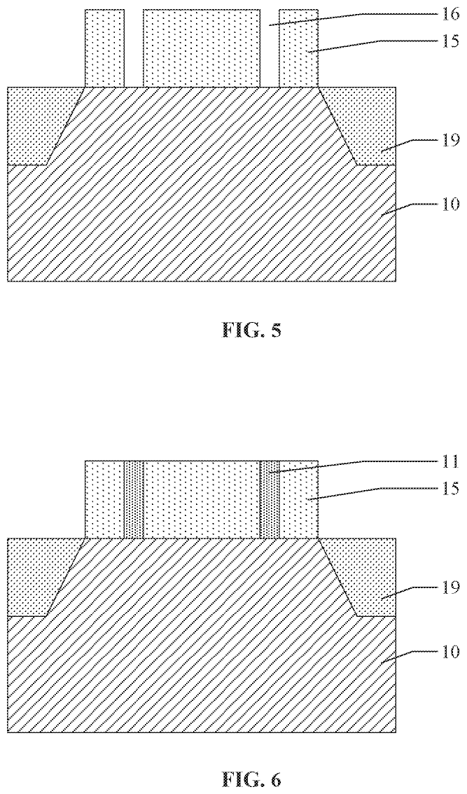

At S203, the first side walls 11 are formed in the side wall grooves 16, as shown in FIG. 6.

At S204, the sacrificial layer 15 is removed, as shown in FIG. 7.

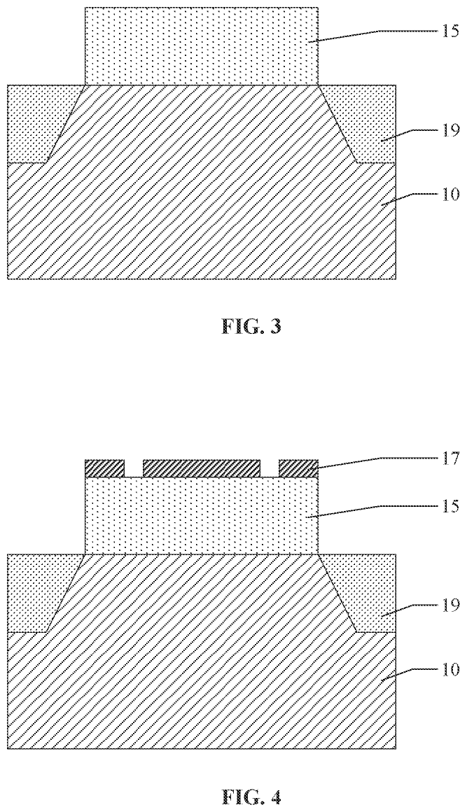

In the above operations, as shown in FIG. 4, a photoresist layer 17 is formed on the sacrificial layer 15, the photoresist layer 17 is patterned by exposure and development. Part of the sacrificial layer 15 is exposed. The exposed portion of the sacrificial layer is removed by dry etching so as to obtain two side wall grooves 16. The sacrificial layer 15 may be an oxide layer. The materials of the sacrificial layer 15 and the first side walls 11 have a higher etching selection ratio. The first side wall 11 may be silicon-containing dielectric layer formed by deposition. In an optional example, the first side wall 11 include a silicon nitride layer or silicon dioxide layer. When the first side wall 11 is a silicon nitride layer, the sacrificial layer 15 may be a silicon dioxide layer. After the first side wall 11 is formed, the sacrificial layer 15 is removed by a wet etching process. There is an interval between the two first side walls 11, the size of the interval is determined according to the size of the gate layer 14 obtained in the subsequent process, and the two first side walls 11 are located at two ends of the gate layer 14.

In another optional example, S20 specifically includes the following operations.

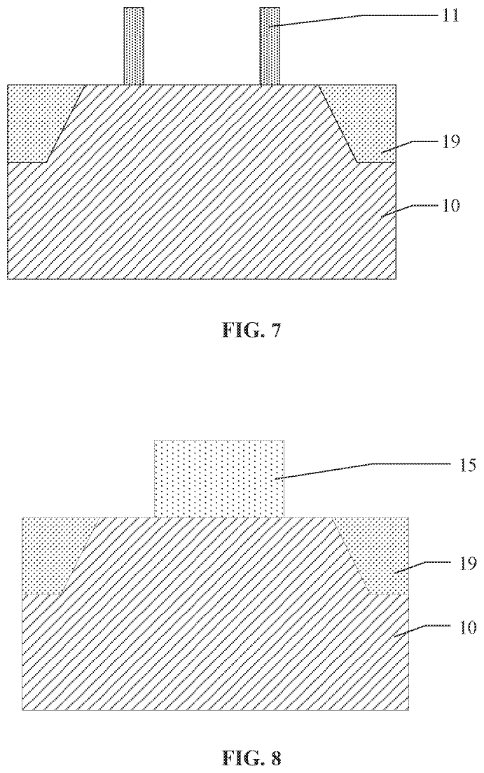

At S201, a sacrificial layer 15 is formed on the substrate 10, as shown in FIG. 8.

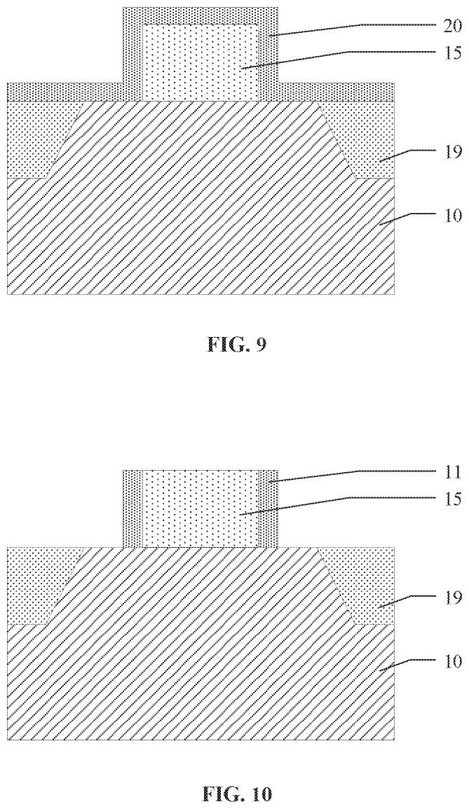

At S202, a first side wall material layer 20 is formed on the upper surface of the sacrificial layer 15, the side wall of the sacrificial layer 15 and the upper surface of the substrate 10, as shown in FIG. 9.

At S203, the first side wall material layer 20 on the upper surface of the sacrificial layer 15 and the upper surface of the substrate 10 is removed to reserve the first side wall material layer 20 on the side walls of the sacrificial layer 15, so as to form the first side walls 11, as shown in FIG. 10.

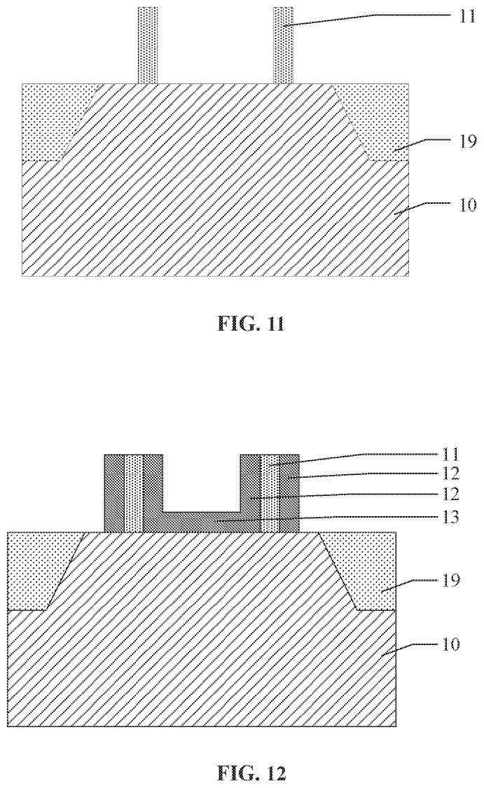

At S204, the sacrificial layer 15 is removed, as shown in FIG. 11.

Specifically, the sacrificial layer 15 may be formed on the upper surface of the substrate 10 through a deposition process. The material of the sacrificial layer 15 may be an oxide, such as silicon dioxide. The first side wall material layer 20 may also be formed on the upper surface of the substrate 10, the upper surface of the sacrificial layer 15 and the side wall of the sacrificial layer 15 through a deposition process. The material of the first side wall material layer 20 may be a silicon-containing dielectric layer. In an optional example, the first side wall material layer 20 may be a silicon nitride layer or a silicon dioxide layer. Materials of the sacrificial layer 15 and the first side wall material layer 20 have a larger etching selection ratio. When the first side wall material layer 20 is a silicon nitride layer, the sacrificial layer 15 may be a silicon dioxide layer. The first side wall material layer 20 on the upper surface of the sacrificial layer 15 and the upper surface of the substrate 10 may be removed by a dry etching process, the first side wall material layer 20 on the upper surface of the sacrificial layer 15 may also be removed by a chemical mechanical grinding process, and the sacrificial layer 15 may be removed by a wet etching process. After removing the sacrificial layer 15, an interval is formed between the two first side walls 11. The size of the interval is determined according to the size of the gate layer 14 obtained in the subsequent process, and the two first side walls 11 are located at two ends of the gate layer 14.

In an optional example, for S30, as shown in FIG. 12, the formation of the second side walls 12 by the ISSG process is performed under a temperature of 800° C. to 1100° C. In an optional example, during the formation of the second side walls 12, the temperature may be 800° C., 900° C., 1000° C., or 1100° C. In the ISSG process, the reaction pressure is 6 Torr to 20 Torr. In an optional example, the reaction pressure of 6 Torr, 8 Torr, 12 Torr or 20 Torr may be used. During the formation of the second side walls 12 by the ISSG process, the reaction gas includes a mixed gas of oxygen and hydrogen, a mixed gas of nitric oxide and hydrogen or a mixed gas of nitrogen dioxide and hydrogen. The volume concentration of hydrogen is 1% to 33%. In an optional example, the volume concentration of the hydrogen may be 1%, 10%, 20% or 33%.

The second side wall 12 is formed at either sides of each of the first side walls 11, and at the same time, a gate oxide layer 13 is formed between a pair of first side walls 11. In an optional example, both the second side wall 12 and the gate oxide layer 13 are made by oxides, such as silicon dioxide. The second side wall 12 and the gate oxide layer 13 may be formed by the same ISSG process. The thickness of the first side wall 11 is greater than the thickness of the second side wall 12.

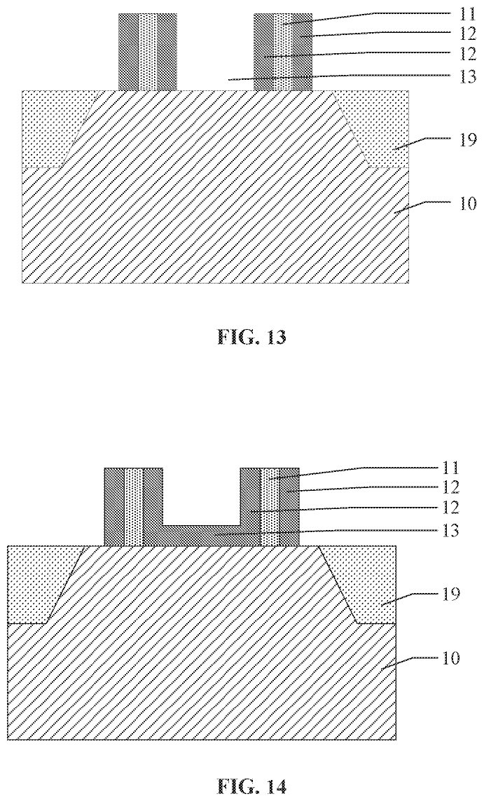

In other optional example, as shown in FIG. 13 and FIG. 14, the second side wall 12 is first formed at either side of each of the first side walls 11 by the ISSG process, and then, the gate oxide layer 13 is formed on the upper surface of the substrate 10 between the two first side walls 11 by the ISSG process or other processes such as a deposition process. The second side wall 12 and the gate oxide layer 13 are made by oxides, such as silicon dioxide.

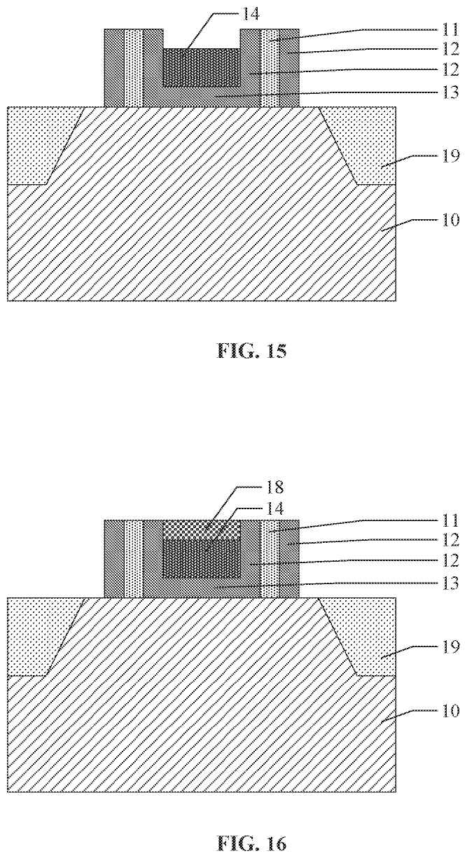

For S40, as shown in FIG. 15, specifically, polysilicon or metal is deposited on the upper surface of the gate oxide layer 13 between a pair of first side walls 11 to form the gate layer 14, the gate layer 14 is filled between the second side walls 12 at the pair of first side walls 11, and the upper surface of the gate layer 14 is lower than the upper surfaces of the first side walls 11.

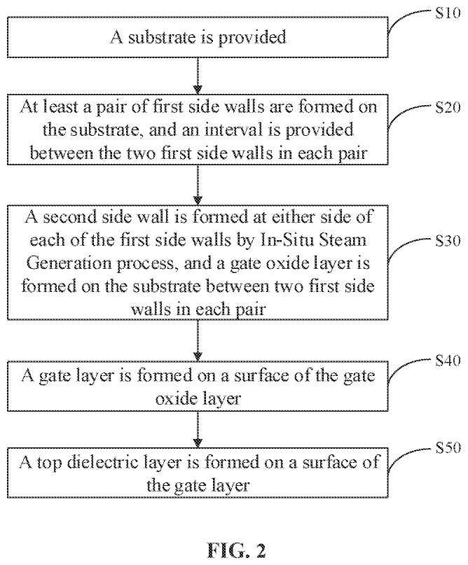

As shown in FIG. 2, in an optional example, after S40, the method further includes S50.

At S50, a top dielectric layer 18 is formed on the surface of the gate layer 14, as shown in FIG. 16.

For S50, specifically, silicon nitride or silicon oxide is deposited on the upper surface of the gate layer 14 by a deposition process to form a top dielectric material layer. The top dielectric material layer is flattened to form the top dielectric layer 18, and the upper surface of the top dielectric layer 18 is flush with the upper surface of each of the first side wall 11.

Through the method for manufacturing the semiconductor structure, since the second side wall 12 is formed by ISSG, the second side wall 12 would have a higher breakdown voltage. Therefore, there are fewer defects in the second side wall 12. Moreover, the second side wall 12 is formed at either side of each of the first side walls 11. On the one hand, the ability of the first side wall 11 and the second side wall 12 to reduce the leakage current of the gate electrode is improved. On the other hand, the second side wall 12 formed at either side of each of the first side walls 11 can reduce the thickness of the second side wall 12 at either side of the first side wall 11, so as to reduce the possibility of defects in the second side wall 12. Therefore, the ability of the first side wall 11 and the second side wall 12 to reduce the leakage current of the gate electrode can be further improved, and the reliability of the device and the service life of the device can be increased.

A semiconductor structure is further provided, as shown in FIG. 16. The semiconductor structure is manufactured according to the method for manufacturing the semiconductor structure. The semiconductor structure includes a substrate 10. The substrate may be a silicon substrate, a silicon-on-insulator substrate, or may be other semiconductor materials including group III, group IV and group V. A shallow trench isolation structure 19 is formed in the substrate 10, and a plurality of active regions are isolated in the substrate 10 by the shallow trench isolation structure 19. The active regions may be doped with doped ions, such as N-type ions or P-type ions. The plurality of active regions are arranged at intervals in the substrate 10.

At least a pair of first side walls 11 are formed on the active regions, and there is an interval between the first side walls 11 in each pair. The first side wall 11 may be silicon-containing dielectric layers formed by deposition. In an optional example, the first side wall 11 includes a silicon nitride layer or silicon dioxide layer.

The second side wall 12 is formed at either side of each of the first side walls 11. The gate oxide layer 13 is formed on the active region between a pair of first side walls 11. The second side wall 12 is connected with the gate oxide layer 13. The materials of the second side walls 12 and the gate oxide layer 13 are both oxides. In an optional example, silicon dioxide may be used. The second side walls 12 and the gate oxide layer 13 may be formed by the same ISSG process.

Polysilicon is deposited on the upper surface of the gate oxide layer 13 to form the gate layer 14. The gate layer 14 is filled between the second side walls 12 at a pair of first side walls 11. The upper surface of the gate layer 14 is lower than the upper surface of each of the first side walls 11.

In other optional example, the top dielectric layer 18 is also formed on the upper surface of the gate layer 14. In addition, the material of the top dielectric layer 18 may be silicon nitride or silicon oxide, and plays a protection effect on the gate layer 14.

Through the above semiconductor structure, the second side walls 12 formed at either side of each of the first side walls 11 can on the one hand, improve the ability of the first side wall 11 and the second side wall 12 to reduce the leakage current of the gate electrode. On the other hand, the second side wall 12 formed at either side of each of the first side walls 11 can reduce the thickness of the second side wall 12 at either side of the first side wall 11, so as to reduce the possibility of defects in the second side walls 12. Therefore, the ability of the first side wall 11 and the second side wall 12 to reduce the leakage current of the gate electrode can be improved, and the reliability and the service life of the device can be increased.

Various technical features in the foregoing examples may be combined freely. In order to describe briefly, the descriptions are not made on all possible combinations of the technical features of the examples. However, the combinations of these technical features should be construed as falling into a scope of the specification as long as there is no conflict in these combinations.

The foregoing examples merely describe several implementation modes of the present application. The description is specific and detailed, but cannot be understood as limitations to a scope of the present application. It should be noted that those of ordinary skill in the art can further make multiple modifications and improvements without departing from a concept of the present application and those also belong to the protection scope of the present application. Therefore, the protection scope of the present application shall be limited by the appended claims.

1. A method for manufacturing a semiconductor structure, comprising:
providing a substrate;
forming at least a pair of first side walls on the substrate, wherein an interval is provided between two first side walls in each pair;
forming a second side wall at either side of the first side walls by an In-Situ Steam Generation process, and forming a gate oxide layer on the substrate between the two first side walls in each pair; and
forming a gate layer on a surface of the gate oxide layer.

2. The method of claim 1, wherein the formation of the first side walls on the substrate comprises:
forming a sacrificial layer on the substrate;
forming the first side walls on the sacrificial layer; and
removing the sacrificial layer.

3. The method of claim 2, wherein the formation of the first side walls on the sacrificial layer comprises:
forming side wall grooves in the sacrificial layer; and
forming the first side walls in the side wall grooves.

4. The method of claim 1, wherein each of the first side walls comprises a silicon-containing dielectric layer.

5. The method of claim 1, wherein each of the first side walls is a silicon nitride layer or silicon dioxide layer, and the second side wall is a silicon dioxide layer.

6. The method of claim 1, wherein after forming the gate layer, further comprising, forming a top dielectric layer on a surface of the gate layer.

7. The method of claim 6, wherein the top dielectric layer comprises a silicon nitride layer or a silicon oxide layer.

8. The method of claim 1, wherein during the formation of the second side wall by the In-Situ Steam Generation process is performed under a reaction temperature is 800° C. to 1100° C., and a reaction pressure of 6 Torr to 20 Torr.

9. The method of claim 1, wherein the formation of the second side wall by the In-Situ Steam Generation process is performed with a reaction gas comprising a mixed gas of oxygen and hydrogen, a mixed gas of nitric oxide and hydrogen or a mixed gas of nitrogen dioxide and hydrogen.

10. The method of claim 9, wherein a volume concentration of hydrogen in the mixed gas is 1% to 33%.

11. A semiconductor structure, manufactured based on the method of claim 1.
